(19) United States
(12) Patent Application Publication
(10) Pub. No.: US 2024/0423024 A1
(43) Pub. Date: Dec. 19, 2024

(54) DISPLAY PANEL AND MANUFACTURING METHOD THEREFOR, DISPLAY DEVICE

(71) Applicant: BOE Technology Group Co., Ltd., Beijing (CN)

(72) Inventors: Hongda SUN, Beijing (CN); Fengjuan LIU, Beijing (CN); Jianye ZHANG, Beijing (CN); Jinglu BAI, Beijing (CN)

(21) Appl. No.: 18/698,597

(22) PCT Filed: Sep. 29, 2022
(86) PCT No.: PCT/CN2022/122715

§ 371 Date: Apr. 4, 2024

(51) Int. Cl. H10K 59/122; H10K 59/12; H10K 59/124

(52) U.S. Cl. CPC H10K 59/122; H10K 59/1201; H10K 59/124

(57) ABSTRACT

A display panel includes: a first substrate, a driving circuit layer including a plurality of thin-film transistors, a planarization layer including a first portion, a second portion, and a third portion; where a thickness of the first portion is less than that of the second portion, and a thickness of the third portion is less than that of the second portion; the first portion includes a first through hole; a light-emitting device including an anode, where the anode covers the first portion and a lateral surface adjacent to the first portion, of the second portion, and an angle between a surface at a side away from the first substrate, of a part of the anode covering the lateral surface of the second portion and a surface parallel to a plane where the first substrate is located, of the anode, is greater than 0.

### CROSS-REFERENCE TO RELATED APPLICATIONS

This application is a National Stage of International Application No. PCT/CN2022/122715, filed on Sep. 29, 2022, which is hereby incorporated by reference in its entirety.

### TECHNICAL FIELD

The disclosure relates to the display technology field, and in particular to a display panel and a manufacturing method therefor, and a display device.

### BACKGROUND

Organic light-emitting diode (OLED) devices have become a highly competitive and promising next-generation display technology due to their advantages such as all-solid-state structure, high brightness, full viewing angle, fast response speed, and wide operating temperature range.

At present, an OLED display product includes a plurality of subpixels, and the subpixels include OLED devices, but there is a problem of lateral light leakage between adjacent subpixels, which affects the display effect.

### SUMMARY

Some embodiments of the present disclosure provide a display panel, including a plurality of subpixels, the display panel includes:
a first substrate;
a driving circuit layer located on a side of the first substrate and including a plurality of thin-film transistors;
a planarization layer located on a side away from the driving circuit layer, of the first substrate, and including: a plurality of first portions, a plurality of second portions, and a plurality of third portions; where in a direction perpendicular to the first substrate, a thickness of the first portion is less than a thickness of the second portion, and a thickness of the third portion is less than the thickness of the second portion; an orthographic projection of the second portion on the first substrate encloses an orthographic projection of the first portion on the first substrate; the orthographic projection of the first portion on the first substrate covers an orthographic projection of a light-emitting region of a subpixel on the first substrate, and an orthographic projection of the third portion on the first substrate is within an orthographic projection of a region between light-emitting regions of adjacent subpixels on the first substrate; the first portion includes a first through hole penetrating through the thickness of the first portion;
a plurality of light-emitting devices located on a side away from the first substrate, of the planarization layer; where the light-emitting device includes an anode; the anode covers the first portion and a lateral surface adjacent to the first portion, of the second portion; an angle between a surface at a side away from the first substrate, of a part of the anode covering the lateral surface of the second portion and a surface parallel to a plane where the first substrate is located, of the anode, is greater than 0; the anode is electrically connected with the thin-film transistor through the first through hole;
a pixel definition layer located on a side away from the planarization layer, of the anode; where an orthographic projection of the pixel definition layer on the first substrate covers an orthographic projection of the first through hole on the first substrate.

In some embodiments, the angle between the surface at the side away from the first substrate, of the part of the anode covering the lateral surface of the second portion and a side parallel to the plane where the first substrate is located, of the anode, is greater than or equal to 30° and less than or equal to 50°.

In some embodiments, in the direction perpendicular to the first substrate, the thickness of the first portion is equal to the thickness of the third portion.

In some embodiments, in the direction perpendicular to the first substrate, a difference between the thickness of the second portion and the thickness of the first portion is greater than or equal to 0.5 μm and less than or equal to 1 μm.

In some embodiments, the pixel definition layer includes a plurality of first opening regions and a plurality of second opening regions; an orthographic projection of the first opening region on the first substrate is within the orthographic projection of the first portion on the first substrate, an orthographic projection of the second opening region on the first substrate is within the orthographic projection of the third portion on the first substrate; the orthographic projection of the second portion on the first substrate is within the orthographic projection of the pixel definition layer on the first substrate.

In some embodiments, a ratio of area of an overlapping region of the orthographic projection of the second portion on the first substrate and the orthographic projection of the pixel definition layer on the first substrate to area of the orthographic projection of the pixel definition layer on the first substrate is less than or equal to 76%.

In some embodiments, a maximum distance between a surface at a side away from the first substrate, of the pixel definition layer and the first portion is greater than or equal to 1.5 μm and less than or equal to 2.5 μm.

In some embodiments, the display panel further includes: the driving circuit layer located between the first substrate and the planarization layer, and including the plurality of thin-film transistors;
where the first portion includes the first through hole penetrating through the thickness of the first portion, the anode is electrically connected with the thin-film transistor through the first through hole;
the orthographic projection of the pixel definition layer on the first substrate covers the orthographic projection of the first through hole on the first substrate.

In some embodiments, the display panel further includes:
a plurality of auxiliary electrodes arranged in a layer same with a layer where the anode is located, and insulated from the anode; an orthographic projection of the auxiliary electrode on the first substrate is within the orthographic projection of the second portion on the first substrate.

In some embodiments, the pixel definition layer further includes a plurality of third opening regions, and an orthographic projection of the third opening region on the first substrate is within the orthographic projection of the auxiliary electrode on the first substrate.

In some embodiments, the pixel definition layer includes a plurality of fourth portions and a plurality of fifth portions, the fourth portion includes the third opening region, and an orthographic projection of the fifth portion on the first substrate covers the orthographic projection of the first through hole on the first substrate;
the fourth portion and the fifth portion are connected in one piece.

In some embodiments, a transmittance of the pixel definition layer to light with a wavelength greater than or equal to 380 nm and less than or equal to 700 nm is less than 5%.

In some embodiments, the display panel of further includes: a second substrate on a side away from the first substrate, of the pixel definition layer, and a filling layer between the second substrate and the pixel definition layer.

In some embodiments, a distance h between adjacent first opening regions satisfies:

$$h \geq a \times b / ( d - b ) ;$$

where a is a distance between the second substrate and the anode covering the first portion in the direction perpendicular to the first substrate, d is a distance between the second portion and the first portion in the direction perpendicular to the first substrate, and b is a maximum width of the first opening region in a direction parallel to a plane where the first substrate is located.

In some embodiments, a distance h between adjacent first opening regions satisfies:

$$h \geq a \times b / ( c - b ) ;$$

where a is a distance between the second substrate and the anode covering the first portion in the direction perpendicular to the first substrate, c is a maximum distance between a side away from the first substrate, of the pixel definition layer and the first portion in the direction perpendicular to the first substrate, and b is a maximum width of the first opening region in a direction parallel to a plane where the first substrate is located.

In some embodiments, the display panel further includes a curved-surface region;
in the curved-surface region, a distance h between two adjacent first opening regions satisfies:

$$h \geq ( a - d ) \times b / ( ( \frac{1}{K} - a ) \times d \times K ) ;$$

where a is a distance between the second substrate and the anode covering the first portion in the direction perpendicular to the first substrate, d is a distance between the second portion and the first portion in the direction perpendicular to the first substrate, b is a maximum width of the first opening region in a direction parallel to a plane where the first substrate is located, and K is a curvature of the curved-surface region.

In some embodiments, the display panel further includes a curved-surface region;
in the curved-surface region, a distance h between two adjacent first opening regions satisfies:

$$h \geq ( a - c ) \times b / ( ( \frac{1}{K} - a ) \times c \times K ) ;$$

where a is a distance between the second substrate and the anode covering the first portion in the direction perpendicular to the first substrate, c is a maximum distance between a side away from the first substrate, of the pixel definition layer and the first portion in the direction perpendicular to the first substrate, b is a maximum width of the first opening region in a direction parallel to a plane where the first substrate is located, and K is a curvature of the curved-surface region.

Some embodiments of the present disclosure provide a method for manufacturing a display panel, including:
forming a driving circuit layer on a side of a first substrate; where the driving circuit layer includes a plurality of thin-film transistors;
forming a pattern of a planarization layer on a side away from the first substrate, of the driving circuit layer; where the planarization layer includes: a plurality of first portions, a plurality of second portions, and a plurality of third portions; in a direction perpendicular to the first substrate, a thickness of the first portion is less than a thickness of the second portion, and a thickness of the third portion is less than the thickness of the second portion; an orthographic projection of the second portion on the first substrate encloses an orthographic projection of the first portion on the first substrate; the orthographic projection of the first portion on the first substrate covers an orthographic projection of a light-emitting region of a subpixel on the first substrate; an orthographic projection of the third portion on the first substrate is within an orthographic projection of a region between light-emitting regions of adjacent subpixels on the first substrate; the first portion includes a first through hole penetrating through the first portion;
forming a plurality of anodes on a side away from the first substrate, of the planarization layer; the anode covers the first portion and a lateral surface adjacent to the first portion, of the second portion, an angle between a surface at a side away from the first substrate, of a part of the anode covering the lateral surface of the second portion and a surface parallel to a plane where the first substrate is located, of the anode, is greater than 0; the anode is electrically connected with the thin-film transistor through the first through hole;
forming a pattern of a pixel definition layer on a side away from the planarization layer, of the anode; an orthographic projection of the pixel definition layer on the first substrate covers an orthographic projection of the first through hole on the first substrate.

In some embodiments, the forming the pattern of the planarization layer on the side away from the first substrate, of the driving circuit layer, includes:
depositing a planarization layer material on the side away from the first substrate, of the driving circuit layer to form the planarization layer;
forming the first portions, the second portions and the third portions by performing a halftone masking process on the planarization layer.

In some embodiments, the forming the pattern of the pixel definition layer on the side away from the planarization layer, of the anode, includes:
forming the pixel definition layer on the side away from the planarization layer, of the anode;
forming a plurality of first opening regions and a plurality of second opening regions by a patterning process; an orthographic projection of the first opening region on the first substrate is within the orthographic projection of the first portion on the first substrate, an orthographic projection of the second opening region on the first substrate is within the orthographic projection of the third portion on the first substrate, the orthographic projection of the second portion on the first substrate is within the orthographic projection of the pixel definition layer on the first substrate.

Some embodiments of the present disclosure provide a display device, including the display panel according to embodiments of the present disclosure.

### BRIEF DESCRIPTION OF FIGURES

In order to more clearly illustrate technical solutions in embodiments of the present disclosure, the drawings required in the description of embodiments will be briefly described below, and it is obvious that the drawings described below are only some embodiments of the present disclosure, and other drawings can be obtained according to these drawings without creative labor on the premise of those skilled in the art.

FIG. 1 is a schematic diagram of a structure of a display panel according to an embodiment of the present disclosure;

FIG. 2 is a schematic diagram of a structure of another display panel according to an embodiment of the present disclosure;

FIG. 3 is a schematic diagram of a structure of another display panel according to an embodiment of the present disclosure;

FIG. 4 is a schematic diagram of a structure of another display panel according to an embodiment of the present disclosure;

FIG. 5 is a schematic diagram of a structure of another display panel according to an embodiment of the present disclosure;

FIG. 6 is a schematic diagram of relevant dimensions of a display panel according to an embodiment of the present disclosure;

FIG. 7 is a schematic diagram of relevant dimensions of another display panel according to an embodiment of the present disclosure;

FIG. 8 is a schematic diagram of relevant dimensions of another display panel according to an embodiment of the present disclosure;

FIG. 9 is a schematic diagram of relevant dimensions of another display panel according to an embodiment of the present disclosure;

FIG. 10 is a schematic diagram of a first opening region of a display panel according to an embodiment of the present disclosure;

FIG. 11 is a schematic diagram of a first opening region of another display panel according to an embodiment of the present disclosure;

FIG. 12 is a schematic diagram of a first opening region of another display panel according to an embodiment of the present disclosure;

FIG. 13 is a schematic diagram of a first opening region of another display panel according to an embodiment of the present disclosure;

FIG. 14 is a schematic diagram of a first opening region of another display panel according to an embodiment of the present disclosure;

FIG. 15 is a schematic diagram of a first opening region of another display panel according to an embodiment of the present disclosure;

FIG. 16 is a schematic diagram of a first opening region of another display panel according to an embodiment of the present disclosure;

FIG. 17 is a schematic diagram of the first opening region of another display panel according to an embodiment of the present disclosure;

FIG. 18 is a schematic diagram of a first opening region of another display panel according to an embodiment of the present disclosure;

FIG. 19 is a schematic diagram of a first opening region of another display panel according to an embodiment of the present disclosure;

FIG. 20 is a schematic diagram of a first opening region of another display panel according to an embodiment of the present disclosure;

FIG. 21 is a schematic diagram of a first opening region of another display panel according to an embodiment of the present disclosure;

FIG. 22 is a schematic diagram of a first opening region of another display panel provided by the embodiment of the present disclosure;

FIG. 23 is a schematic diagram of a first opening region of another display panel according to an embodiment of the present disclosure;

FIG. 24 is a schematic diagram of a structure of another display panel according to an embodiment of the present disclosure;

FIG. 25 is a schematic diagram of a structure of another display panel according to an embodiment of the present disclosure;

FIG. 26 is a schematic diagram of a structure of another display panel according to an embodiment of the present disclosure;

FIG. 27 is a schematic diagram of a structure of another display panel according to an embodiment of the present disclosure;

FIG. 28 is a schematic diagram of a flow of a method for manufacturing a display panel according to an embodiment of the present disclosure.

### DETAILED DESCRIPTION

In order to make the purpose, technical solution and advantages of embodiments of the present disclosure clearer, the technical solutions of embodiments of the present disclosure will be clearly and completely described below in conjunction with the accompanying drawings of embodiments of the present disclosure. Obviously, embodiments described are some embodiments of the present disclosure, not all embodiments, and in the absence of conflict, embodiments in the present disclosure and the features in embodiments may be combined with each other. Based on embodiments of the present disclosure described, all other embodiments obtained by a person skilled in the art without creative labor are within the scope of protection of the present disclosure.

Unless otherwise defined, the technical or scientific terms used in this disclosure shall have the ordinary meaning understood by persons with general skill in the field to which this disclosure belongs. The terms “first”, “second” and similar terms used in this disclosure do not indicate any order, number or importance, but merely to distinguish between the different components. Words such as “include” or “comprise” mean that the element or object that precedes the word includes the element or object listed after the word and its equivalents, and does not exclude other elements or objects. Similar terms such as “connection” or “link” are not limited to physical or mechanical connections, but may include electrical connections, whether direct or indirect.

It should be noted that the dimensions and shapes of the figures in the drawings do not reflect the true proportions, and are intended to illustrate the contents of this disclosure, and that the same or similar designation at all times indicates the same or similar element or component with the same or similar function.

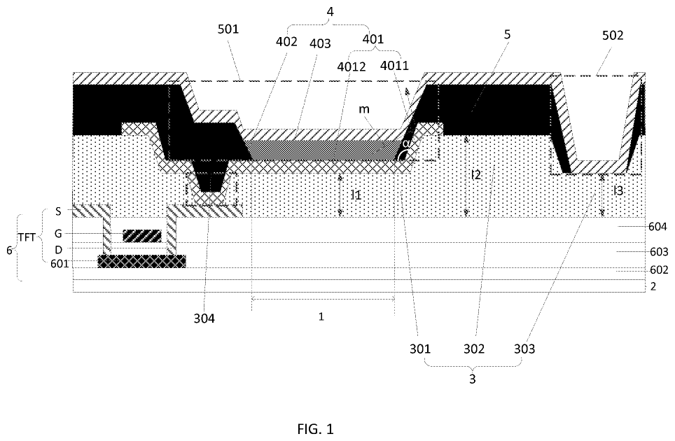

An embodiment of the disclosure provides a display panel, as shown in FIG. 1, includes a plurality of subpixels, and the display panel includes:
a first substrate 2;
a driving circuit layer 22 located on a side of the first substrate 2, and including a plurality of thin-film transistor TFTs;
a planarization layer 3 located on a side away from the driving circuit layer 22, of the first substrate 2 and including: a plurality of first portions 301, a plurality of second portions 302, and a plurality of third portions 303; in a direction perpendicular to the first substrate 2, a thickness 11 of the first portion 301 is less than a thickness 12 of the second portion 302, and a thickness 13 of the third portion 303 is less than the thickness 12 of the second portion 302; an orthographic projection of the second portion 302 on the first substrate 2 encloses an orthographic projection of the first portion 301 on the first substrate 2; the orthographic projection of the first portion 301 on the first substrate 2 covers an orthographic projection of a light-emitting region 1 of a subpixel on the first substrate 2, and an orthographic projection of the third portion 303 on the first substrate 2 is within an orthographic projection of a region between light-emitting regions of adjacent subpixels 1 on the first substrate 2; the first portion 301 includes a first through hole 304 penetrating the thickness of the first portion 301;
a plurality of light-emitting devices 4 located on a side away from the first substrate 2, of the planarization layer 3; the light-emitting device 4 includes an anode 401; the anode 401 covers the first portion 301 and a lateral surface of the second portion 302 adjacent to the first portion 301, and an angle α between a surface at a side away from the first substrate 2, of a part of the anode 401 covering the lateral surface of the second portion 302 and a surface of the anode 401 parallel to a plane where the first substrate 2 is located, is greater than 0; the anode 401 is electrically connected with the thin-film transistor TFT through the first through hole 304;
a pixel definition layer 5 located on a side away from planarization layer 3, of the anode 401; an orthographic projection of the pixel definition layer 5 on the first substrate 2 covers an orthographic projection of the first through hole on the first substrate 2.

In order to facilitate distinction, as shown in FIG. 1, the part of the anode 401 covering the lateral surface of the second portion 302 is called a first anode portion 4011, and the part of the anode 401 covering the first portion 301 is called a second anode portion 4012.

In the display panel according to embodiments of the present disclosure, the planarization layer includes the first portion and the second portion which are adjacent to each other and of different thicknesses. The first portion corresponds to the light-emitting region of the subpixel, that is, the planarization layer has a concave part in the region corresponding to the light-emitting region of the subpixel, so that the angle between the lateral surface of the second portion and the surface at the side away from the first substrate, of the first portion is greater than 0, so that when the anode covers the lateral surface of the second portion adjacent to the first portion, the angle α between a surface at a side away from the first substrate, of the first anode portion and a surface of the first anode portion parallel to a plane where the first substrate is located, is greater than 0, that is, the angle between the first anode portion and the second anode portion is greater than 0, and the part of the anode covering the lateral surface of the second portion can be used as a reflective layer to reflect light emitted laterally (in a direction pointing to the first portion) by the light-emitting device. For example, in FIG. 1, the first anode portion 4011 reflects the light m, so as to avoid the situation of lateral light leakage of the subpixel and improve the display effect. Moreover, the planarization layer further includes the third portion adjacent to the second portion and of the thickness different from that of the second portion. The third portion is located in the region between the light-emitting regions of the subpixels, that is, the planarization layer has a concave part in the region between the light-emitting regions of the subpixels, so that the segment difference between the light-emitting region of the subpixel and the region outside the light-emitting region of the subpixel can be increased. The concave part can accommodate the filling material in the box aligning process, and is conducive to the filling and drainage of the filling material, and can also play a pressure dividing role in the box aligning process, avoid the damage to each film layer on a side of the array substrate during the pressing process, and improve the yield of the top emission display panel. In addition, for the flexible display panel, the arrangement of the concave region can reduce the force applied to the region corresponding to the light-emitting region of the subpixel during the bending process of the display panel, which is conducive to avoiding the bending and fracture of each film layer in the region corresponding to the light-emitting region of the subpixel. In addition, the first through hole is arranged in the first portion so that the anode and the thin-film transistor are electrically connected, that is, the first through hole is formed in the region of the planarization layer with a less thickness, and the depth of the first through hole is shallower, which can reduce the difficulty of preparing the first through hole, and can also reduce the thickness of the photoresist coating in the preparation process of the first through hole, and reduce the risk of residue after the photoresist is peeled off. In addition, the orthographic projection of the pixel definition layer on the first substrate covers the orthographic projection of the first through hole on the first substrate, that is, the region corresponding to the first through hole is covered by the pixel definition layer, so that the region of the first through hole is flattened.

In some embodiments, as shown in FIG. 1, the light-emitting device 4 further includes: a light-emitting functional layer 402 located on a side away from the first portion 301, of the anode 401, and a cathode 403 located on a side away from the anode 401, of the light-emitting functional layer 402.

In an embodiment, the light-emitting device is an organic light-emitting diode device. The light-emitting functional layer includes an organic light-emitting layer, and may also include an electron injection layer, an electron transport layer, a hole transport layer, a hole injection layer, etc.

In some embodiments, the angle between the lateral surface of the second portion 302 and the surface at the side away from the first substrate 2, of the first portion 301 is greater than or equal to 30° and less than or equal to 50°. Correspondingly, the angle α between a surface at a side away from the first substrate 2, of the part of the anode 401 covering the lateral surface of the second portion 302 and a surface of the anode 401 parallel to a plane where the first substrate 2 is located, is greater than or equal to 30° and less than or equal to 50°. That is, the angle α between the first anode portion 4011 and the second anode portion 4012 is greater than or equal to 30° and less than or equal to 50°.

It should be noted that the larger the angle α is, the larger the reflection angle of the first anode is, so that the effect of preventing lateral light leakage can be improved, and the excessive angle may also make the light emitted by the far-end of the light-emitting region of the subpixel be reflected by the first anode at the angle to the light-emitting region of other subpixels, resulting in light leakage. In the display panel according to embodiments of the disclosure, the angle α between the first anode portion 4011 and the second anode portion 4012 is greater than or equal to 30° and less than or equal to 50°, so that the effect of using the first anode portion to alleviate lateral light leakage can be guaranteed.

In some embodiments, as shown in FIG. 1, the thickness 11 of the first portion 301 is equal to the thickness 13 of the third portion 303 in the direction perpendicular to the first substrate 2.

In specific implementation, the material of the planarization layer may be, for example, materials such as acrylic or polyimide, so that the planarization layer can be made by photolithography. When making the planarization layer, the halftone mask process can be adopted, the exposure amount of the first portion is different from that of the second portion, and the exposure amount of the second portion is different from that of the third portion. When the thickness of the first portion and the thickness of the third portion is the same, the exposure amount of the first portion and the exposure amount of the third portion are the same, and the difficulty of making the planarization layer can be reduced.

In some embodiments, the difference between the thickness 12 of the second portion 302 and the thickness 11 of the first portion 301 in the direction perpendicular to the first substrate 2, i.e., 12-11, is greater than or equal to 0.5 μm and less than or equal to 1 μm.

In this way, when the thickness of the planarization layer is determined, the size of the region where the anode serves as the reflective layer can be increased as much as possible while ensuring the flatness of the film layer below the first portion, and the lateral light emitting is reflected as much as possible, which is more conducive to alleviating the lateral light leakage of the subpixels.

Correspondingly, when 11=13, 12-13 is greater than or equal to 0.5 μm and less than or equal to 1.

In some embodiments, as shown in FIG. 1, the pixel definition layer 5 includes a plurality of first opening regions 501 and a plurality of second opening regions 502. The orthographic projection of the first opening region 501 on the first substrate 2 is within the orthographic projection of the first portion 301 on the first substrate 2, and the orthographic projection of the second opening region 502 on the first substrate 2 is within the orthographic projection of the third portion 303 on the first substrate 2. The orthographic projection of the second portion 302 on the first substrate 2 is within the orthographic projection of the pixel definition layer 5 on the first substrate 2.

In an embodiment, the pixel definition layer covers the first anode portion and the edge of the second anode portion. The first opening region corresponds to the light-emitting region of the subpixel. The pixel definition layer may also be made of, for example, a material such as acrylic or polyimide.

In some embodiments, the angle between the lateral surface of the pixel definition layer and the second anode portion is greater than or equal to 10° and less than or equal to 50°.

In some embodiments, the pixel definition layer is a shading pixel definition layer. The pixel definition layer 5 has a transmittance of less than 5% for light with a wavelength greater than or equal to 380 nm and less than or equal to 700 nm. That is, the transmittance of the shading pixel definition layer to the light in the visible light band is less than 5%, which can further reduce the lateral light leakage of the light-emitting device and improve the display effect.

In some embodiments, the thickness of the pixel definition layer covering the region of the second portion is greater than or equal to 1 μm and less than or equal to 1.5 μm, and the maximum distance between the surface at the side away from the first substrate 2, of the pixel definition layer 5 and the first portion 301 is greater than or equal to 1.5 μm and less than or equal to 2.5 μm, so as to ensure the shading effect of reducing the lateral leakage of the light-emitting device by the shading pixel definition layer.

In an embodiment, as shown in FIG. 1, the thin-film transistor TFT includes: an active layer 601, a gate G, a source S and a drain D. FIG. 1 illustrates the top-gate structure of a thin-film transistor TFT, which can also be a bottom-gate or other structure. As shown in FIG. 1, the driving circuit layer 6 further includes: a buffer layer 602 between the first substrate and the active layer, a first gate insulating layer 603 between the active layer 601 and the gate G, and an interlayer insulating layer 604 between the first gate insulating layer 603 and the source S and the drain D. The anode 401 is electrically connected with the drain D of the TFT through a first through hole 304.

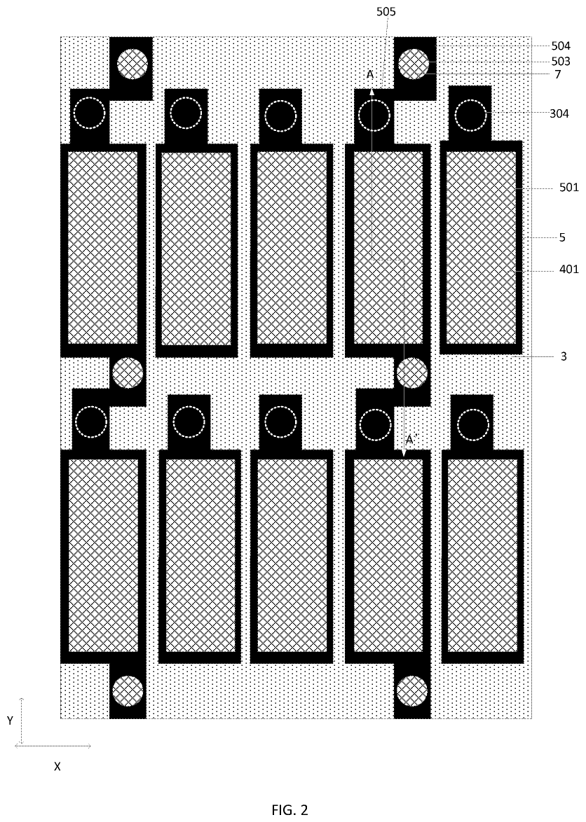

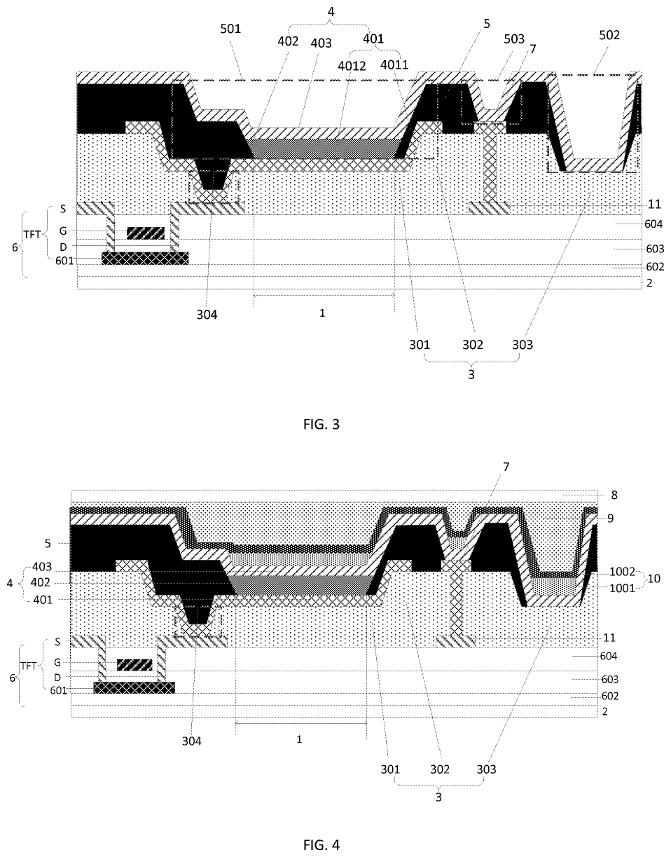

In some embodiments, as shown in FIG. 2 and FIG. 3, the display panel further includes: a plurality of auxiliary electrodes 7 arranged in a layer same with the anode 401 and insulated from the anode 401; an orthographic projection of the auxiliary electrode 7 on the first substrate 2 is within the orthographic projection of the second portion 302 on the first substrate 2.

In the display panel according to an embodiment of the present disclosure, the auxiliary electrode is electrically connected with the cathode, so that a driving signal can be provided to the cathode through the auxiliary electrode. The auxiliary electrode is arranged in the second portion, that is, in the region with a greater thickness of the planarization layer, which can avoid the overlap disconnection caused by the too deep overlap depth between the cathode and the auxiliary electrode, and improve the yield of display panel preparation.

It should be noted that FIG. 3 is a cross-sectional view along the AA′ in FIG. 2.

In some embodiments, as shown in FIG. 3, the display panel further includes a connecting electrode 11 that is electrically connected with the auxiliary electrode 7. The connecting electrode 11 is located between the planarization layer 3 and the interlayer insulating layer 604, and the connecting electrode 11 may be arranged in the same layer as the source S and drain D of the TFT, for example. In specific implementation, a driving signal can be provided to the auxiliary electrode and the cathode by the connecting electrode.

In some embodiments, as shown in FIG. 2 and FIG. 3, the pixel definition layer 5 further includes a plurality of third opening regions 503. An orthographic projection of the third opening region 503 on the first substrate 2 is within the orthographic projection of the auxiliary electrode 7 on the first substrate 2, so as to electrically connect the cathode to the auxiliary electrode in the third opening region.

In some embodiments, as shown in FIG. 2, the pixel definition layer 5 includes a plurality of fourth portions 504 and a plurality of fifth portions 505. The fourth portion 504 has a third opening region 503. An orthographic projection of the fifth portion 505 on the first substrate 2 covers the orthographic projection of the first through hole 304 on the first substrate 2.

The fourth portion 504 and the fifth portion 505 are connected in one piece.

It should be noted that because the fourth portion needs to be provided with the third opening region exposing the auxiliary electrode, so that the cathode is electrically connected with the auxiliary electrode in the third opening region, and in the region outside the light-emitting region of the subpixel, the pixel definition layer also needs to be provided with the second opening region exposing the third portion, in the plane direction parallel to the first substrate, a width of the fourth portion surrounding the third opening region is smaller, and the fourth portion is connected with the fifth portion also in the region outside the light-emitting region of the subpixel as a whole, so that the risk of wire breakage caused by the small width of the pixel definition layer can be reduced, and the yield of the display panel can be improved.

In some embodiments, a ratio of area of an overlapping region of the orthographic projection of the second portion on the first substrate and the orthographic projection of the pixel definition layer on the first substrate to area of the orthographic projection of the pixel definition layer on the first substrate is less than or equal to 76%.

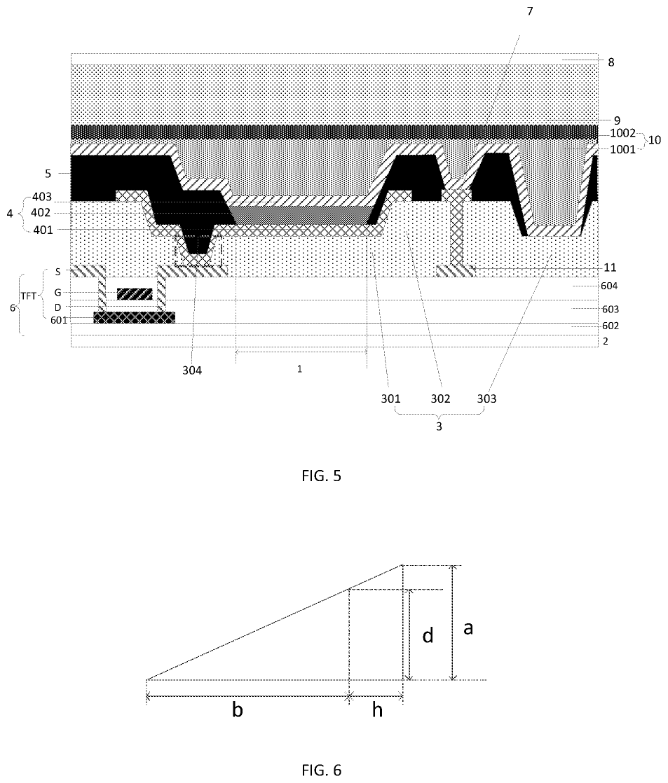

In some embodiments, as shown in FIG. 4 and FIG. 5, the display panel further includes: a second substrate 8 on a side away from the first substrate 2, of the pixel definition layer 5, and a filling layer 9 between the second substrate 8 and the pixel definition layer 5.

In some embodiments, as shown in FIG. 4 and FIG. 5, the display panel further includes: an encapsulation layer 10 between the filling layer 9 and the cathode 403. The encapsulation layer 10 includes an organic encapsulation layer 1001 and a first inorganic encapsulation layer 1002 which are arranged in a stack.

In FIG. 4, the organic encapsulation layer does not fill the uneven regions, i.e., the regions corresponding to the first, second, and third opening portions. The surface away from the first substrate 2, of the subsequently formed first inorganic encapsulation layer 1002 has a concave-convex shape, so that there is still a region that can accommodate the material of the filling layer 9, which is conducive to the filling and drainage of the filling material.

Alternatively, the planarization can be performed using the organic encapsulation layer 1001, as shown in FIG. 5.

Of course, in specific implementation, the encapsulation layer may also include a second inorganic encapsulation layer between the cathode and the organic encapsulation layer.

In some embodiments, a distance h between adjacent first opening regions satisfies:

$$h \geq a \times b / ( d - b ) ;$$

where a is a distance between the second substrate and the anode covering the first portion in the direction perpendicular to the first substrate, d is a distance between the second portion and the first portion in the direction perpendicular to the first substrate, and b is a maximum width of the first opening region in a direction parallel to a plane where the first substrate is located.

In the specific implementation, as shown in FIG. 6, when h=a×b/(d−b), the light emitted laterally by the light-emitting device can be completely reflected by the first anode, so that when h≥a×b/(d−b), the light leakage between the subpixels caused by the lateral light emitting of the light-emitting device can still be completely eliminated, and the specific values of h, a, b, and d can be set according to actual requirements.

In some embodiments, a distance h between adjacent first opening regions satisfies:

$$h \geq a \times b / ( c - b ) ;$$

where a is the distance between the second substrate and the anode covering the first portion in the direction perpendicular to the first substrate; c is the maximum distance between the side away from the first substrate, of the pixel definition layer and the first portion in the direction perpendicular to the first substrate, and b is the maximum width of the first opening region in the direction parallel to the plane where the first substrate is located.

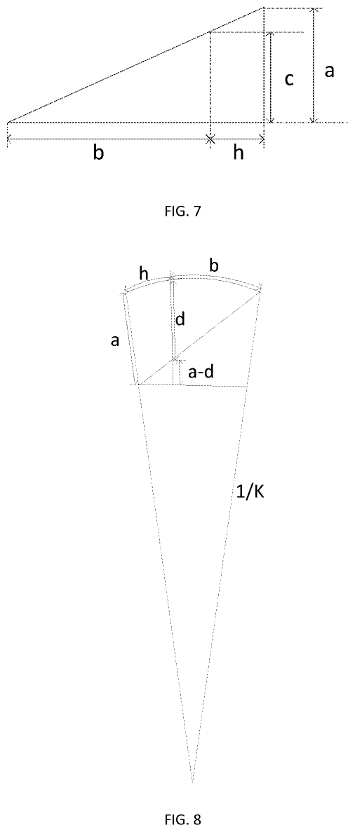

In the specific embodiment, when the pixel definition layer is the shading pixel definition layer, the pixel definition layer can also block the lateral luminescence. Therefore, as shown in FIG. 7, when h=a×b/(c−b), the light emitted laterally by the light-emitting device can be completely eliminated, so that when h≥a×b/(c−b), the light leakage between subpixels caused by the lateral light emitting of the light-emitting device can still be completely eliminated, and the specific values of h, a, b, and c can be set according to actual requirements.

In some embodiments, the display panel includes a curved-surface region.

In the curved-surface region, the distance h between the two adjacent first opening regions satisfies:

$$h \geq ( a - d ) \times b / ( ( \frac{1}{K} - a ) \times d \times K ) ;$$

where a is the distance between the second substrate and the anode covering the first portion in the direction perpendicular to the first substrate, d is the distance between the second portion and the first portion in the direction perpendicular to the first substrate, b is the maximum width of the first opening region in the plane direction parallel to the first substrate, and K is the curvature of the curved-surface region.

In the specific embodiment, 1/K is the radius of curvature of the curved-surface region of the display panel. As shown in FIG. 8, when

$$h = ( a - d ) \times b / ( ( \frac{1}{K} - a ) \times d \times K ,$$

the light emitted laterally by the light-emitting device can be completely reflected by the first anode, so that when

$$h ⩾ ( a - d ) \times b / ( ( \frac{1}{K} - a ) \times d \times K ,$$

the light leakage between the subpixels caused by the lateral light emitting of the light-emitting device can still be completely eliminated, and the specific values of h, a, d, b, and K can be set according to actual requirements.

In some embodiments, the display panel includes a curved-surface region.

In the curved-surface region, the distance h between the two adjacent first opening regions satisfies:

$$h \geq ( a - c ) \times b / ( ( \frac{1}{K} - a ) \times c \times K ) ;$$

where a is the distance between the second substrate and the anode covering the first portion in the direction perpendicular to the first substrate, c is the maximum distance between the side away from the first substrate, of the pixel definition layer and the first portion in the direction perpendicular to the first substrate, b is the maximum width of the first opening region in the plane direction parallel to the first substrate, and K is the curvature of the curved-surface region.

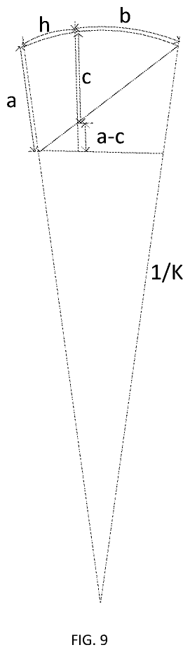

In the specific embodiment, as shown in FIG. 9, when

$$h = ( a - c ) \times b / ( ( \frac{1}{K} - a ) \times c \times K ) ,$$

the light emitted laterally by the light-emitting device can be completely reflected by the first anode portion, so that when

$$h \geq ( a - c ) \times b / ( ( \frac{1}{K} - a ) \times c \times K ) ,$$

the light leakage between subpixels caused by the lateral light emitting of the light-emitting device can still be completely eliminated, and the specific values of h, a, d, b, and K can be set according to actual requirements.

It should be noted that FIG. 2 takes the first opening region being a rectangle as an example, that is, the light-emitting region of the subpixel is a rectangle, and the first opening region of the rectangle is arranged in a regular array along the first direction X and the second direction Y. Of course, in the specific implementation, when the first opening region is a rectangle, the plurality of first opening regions can also adopt other arrangements.

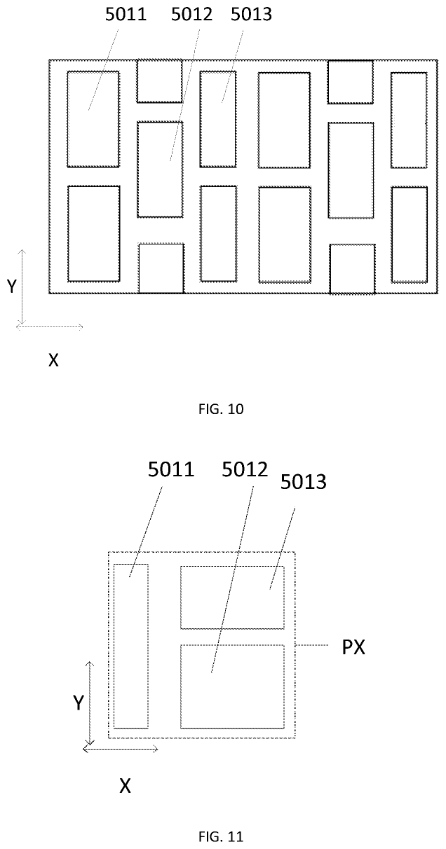

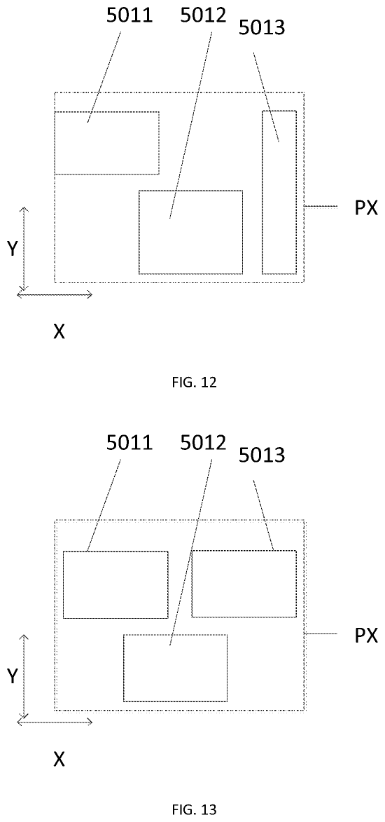

In the specific embodiment, for example, as shown in FIG. 10 to FIG. 13, the plurality of first opening regions include a first subpixel opening region 5011, a second subpixel opening region 5012 and a third subpixel opening region 5013. As shown in FIG. 10, the second subpixel opening region 5012 and the first subpixel opening region 5011 are misaligned, and the second subpixel opening region 5012 and the third subpixel opening region 5013 are misaligned. As shown in FIG. 11, in the first subpixel opening region 5011, the second subpixel opening region 5012 and the third subpixel opening region 5013 included in a pixel PX, the first subpixel opening region 5011 is adjacent to the second subpixel opening region 5012 and the third subpixel opening region 5013 in the first direction X, and the outline formed by arrangement of the first subpixel opening region 5011, the second subpixel opening region 5012 and the third subpixel opening region 5013 included in the pixel is rectangular. As shown in FIG. 12, in the first direction X, the projection of the first subpixel opening region 5011 and the projection of the second subpixel opening region 5012 overlap with the projection of the third subpixel opening region 5013, and the projection of the first subpixel opening region 5011 and the projection of the third subpixel opening region 5013 have a non-overlapping region. In the second direction Y, the projection of the first subpixel opening region 5011 and the projection of the second subpixel opening region 5012 have an overlapping region. As shown in FIG. 13, the first subpixel opening region 5011, the second subpixel opening region 5012 and the third subpixel opening region 5013 included in the pixel PX are arranged in two rows, and lines connecting centers of the first subpixel opening region 5011, the second subpixel opening region 5012 and the third subpixel opening region 5013 form a triangle.

In the specific embodiment, as shown in FIG. 10, FIG. 11 and FIG. 12, areas of the first subpixel opening region 5011, the second subpixel opening region 5012 and the third subpixel opening region 5013 are not identical. Alternatively, as shown in FIG. 13, areas of the first subpixel opening region 5011, the second subpixel opening region 5012 and the third subpixel opening region 5013 are identical.

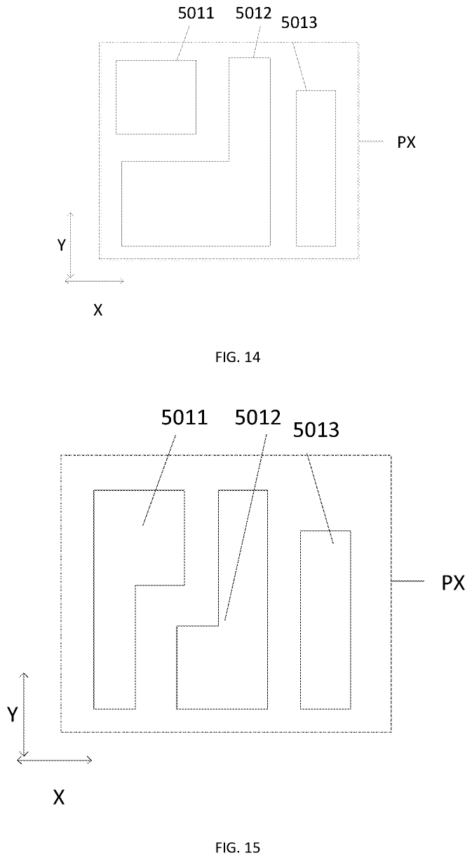

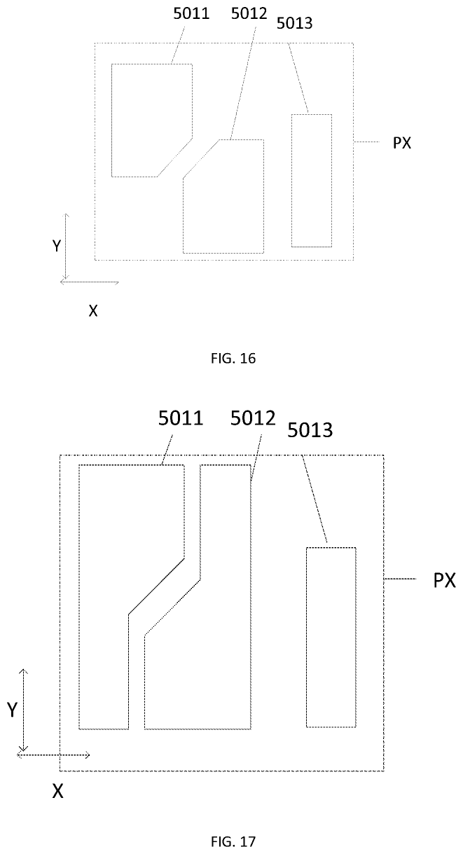

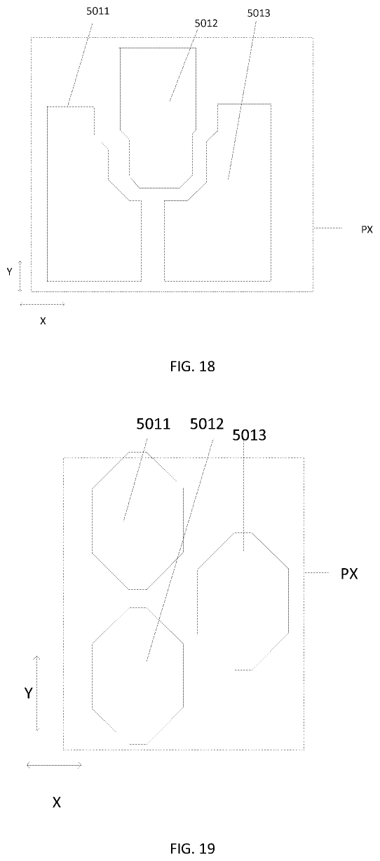

Alternatively, in the specific embodiment, as shown in FIG. 14 to FIG. 18, at least part of the first opening region that is the light-emitting region of the subpixel can also be other shapes. As shown in FIG. 14, the shape of the first subpixel opening region 5011 and the third subpixel opening region 5013 is rectangular, and the shape of the second subpixel opening region 5012 is L-shaped. As shown in FIG. 15, the shape of the first subpixel opening region 5011, and the shape of the second subpixel opening region 5012 are L-shaped, and the shape of the third subpixel opening region 5013 is rectangular. As shown in FIG. 16 and FIG. 17, the shape of the first subpixel opening region 5011 and the shape of the second subpixel opening region 5012 are pentagonal, and the shape of the third subpixel opening region 5013 is rectangular. As shown in FIG. 18, the shape of the first subpixel opening region 5011, the shape of the second subpixel opening region 5012 and the shape of the third subpixel opening region 5013 are irregular polygons.

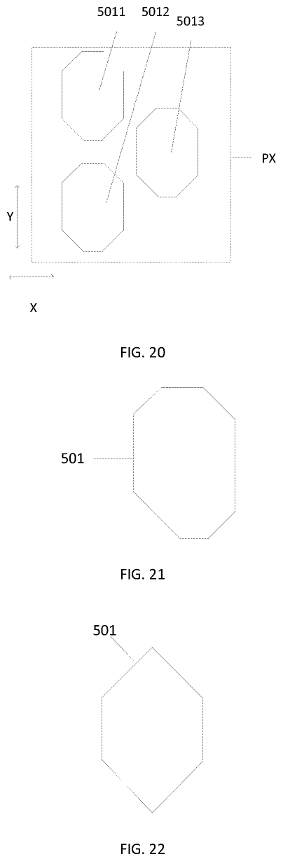

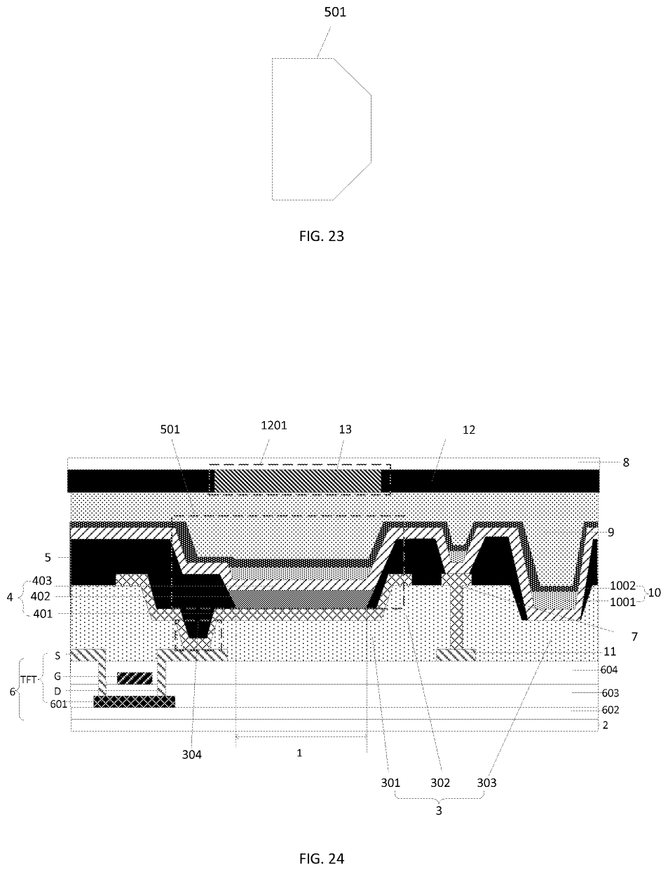

Alternatively, in the specific embodiment, as shown in FIGS. 19 to 23, the first subpixel opening region 5011, the second subpixel opening region 5012 and the third subpixel opening region 5013 are non-rectangular. As shown in FIGS. 19 to 20, the first subpixel opening region 5011, the second subpixel opening region 5012 and the third subpixel opening region 5013 are octagonal, and the first subpixel opening region 5011, the second subpixel opening region 5012 and the third subpixel opening region 5013 included in a pixel PX are arranged in two columns. Lines connecting centers of the first subpixel opening region 5011, the second subpixel opening region 5012 and the third subpixel opening region 5013 form a triangle. The first opening region 501 shown in FIG. 21 is an asymmetrical octagon. The first opening region 501 shown in FIG. 22 is hexagonal, and the first opening region 501 shown in FIG. 23 is heptagonal.

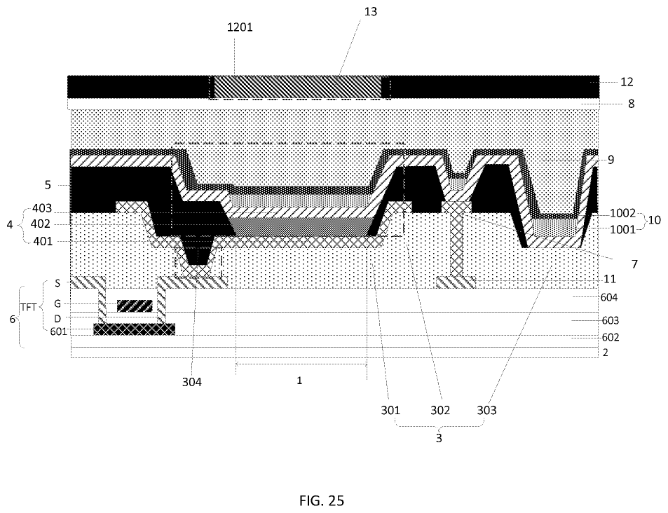

In some embodiments, as shown in FIG. 24 and FIG. 25, the display panel further includes: a first shading layer 12 and a photoluminescent layer 13. The first shading layer 12 includes a fourth opening region 1201 corresponding to the first opening region 11 in one-to-one correspondence. The photoluminescent layer 13 is located in at least part of the fourth opening region 1201. As shown in FIG. 24, the first shading layer 12 and the photoluminescent layer 13 are arranged on a side facing the first substrate 2, of the second substrate 8. Alternatively, as shown in FIG. 25, the first shading layer 12 and the photoluminescent layer 13 are arranged on a side away from the first substrate 2, of the second substrate 8.

In specific implementation, the photoluminescent layer is configured to absorb the light emitted by the light-emitting device to radiate the light of the desired color, so that the display effect can be improved.

In specific implementation, the subpixel includes a red subpixel, a blue subpixel, and a green subpixel.

In some embodiments, the photoluminescent layer is a quantum dot photoluminescent layer.

In some embodiments, a photoluminescent layer is arranged in each fourth opening region.

Alternatively, in some embodiments, only the fourth opening regions corresponding to the red subpixel and the green subpixel are provided with the photoluminescent layer. In this case, the light-emitting devices are all blue light-emitting devices. The photoluminescent layer includes a red quantum dot layer in the fourth opening region corresponding to the red subpixel and a green quantum dot layer in the fourth opening region corresponding to the green subpixel. The red quantum dot layer absorbs blue light and radiates red light, and the green quantum dot layer absorbs blue light and radiates green light. Since the light-emitting device is a blue-light-emitting device, the display panel can be displayed in full color without setting a quantum dot layer in the fourth opening region corresponding to the blue subpixel. The display panel further includes: a translucent filling layer located within the fourth opening corresponding to the blue subpixel.

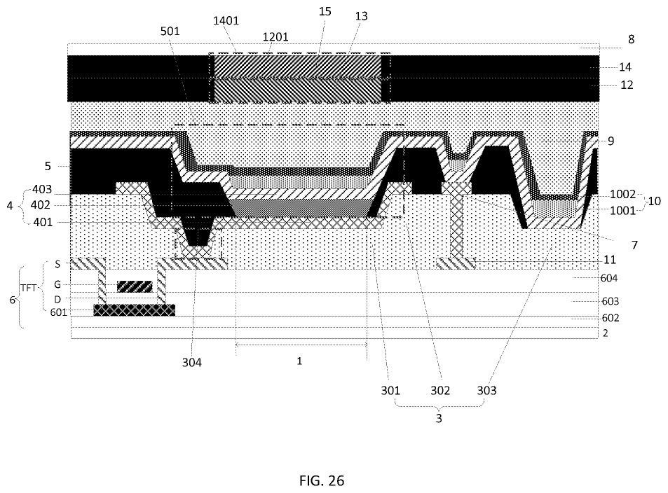

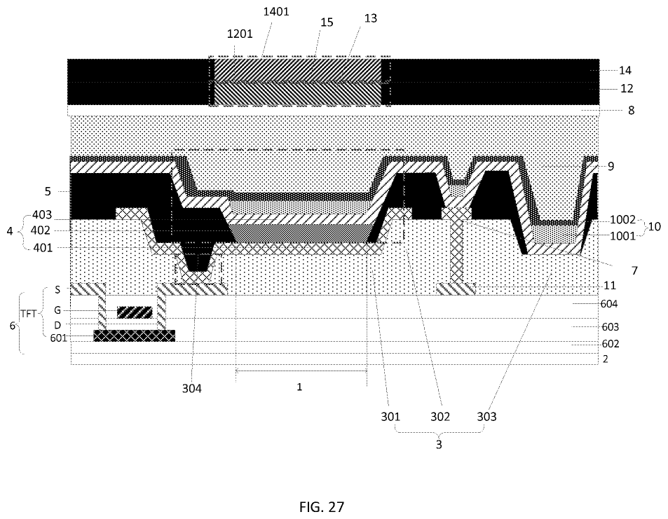

In some embodiments, as shown in FIG. 26 and FIG. 27, the display panel further includes: a second shading layer 14 and a chromatic color resistance 15. The second shading layer 14 includes a fifth opening region 1401 corresponding to the first opening region in one-to-one correspondence. The chromatic color resistance 15 is located in the fifth opening region 1401. In FIG. 26, the second shading layer 14 and the chromatic color resistance 15 are located between the first shading layer 12 and the second substrate 8. In FIG. 27, the second shading layer 14 and the chromatic color resistance 15 are located on a side away from the second substrate 8, of the first shading layer 12.

An embodiment of the disclosure provides a display panel in which a chromatic color resistance is arranged in the region corresponding to the light-emitting region of the subpixel, so that the color purity of the display panel can be improved.

In an embodiment, the chromatic color resistance includes a red color resistance corresponding to a red subpixel, a blue color resistance corresponding to a blue subpixel and a green color resistance corresponding to a green subpixel.

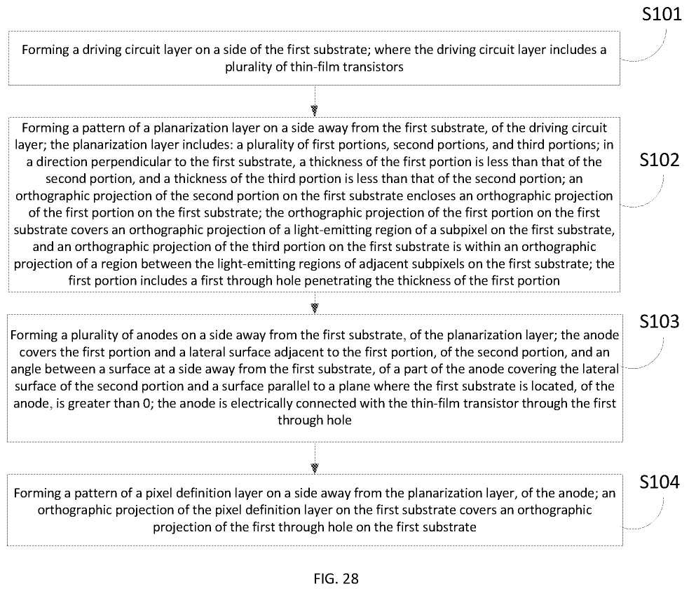

Based on the same disclosure conception, an embodiment of the present disclosure provides a method for manufacturing a display panel, as shown in FIG. 28, including:
S101: forming a driving circuit layer on a side of the first substrate; where the driving circuit layer includes a plurality of thin-film transistors;
S102: forming a pattern of a planarization layer on a side away from the first substrate, of the driving circuit layer; the planarization layer includes: a plurality of first portions, second portions, and third portions; in a direction perpendicular to the first substrate, a thickness of the first portion is less than that of the second portion, and a thickness of the third portion is less than that of the second portion; an orthographic projection of the second portion on the first substrate encloses an orthographic projection of the first portion on the first substrate; the orthographic projection of the first portion on the first substrate covers an orthographic projection of a light-emitting region of a subpixel on the first substrate, and an orthographic projection of the third portion on the first substrate is within an orthographic projection of a region between the light-emitting regions of adjacent subpixels on the first substrate; the first portion includes a first through hole penetrating the thickness of the first portion;
S103: forming a plurality of anodes on a side away from the first substrate, of the planarization layer; the anode covers the first portion and a lateral surface adjacent to the first portion, of the second portion, and an angle between a surface at a side away from the first substrate, of a part of the anode covering the lateral surface of the second portion and a surface parallel to a plane where the first substrate is located, of the anode, is greater than 0; the anode is electrically connected with the thin-film transistor through the first through hole;
S104: forming a pattern of a pixel definition layer on a side away from the planarization layer, of the anode; an orthographic projection of the pixel definition layer on the first substrate covers an orthographic projection of the first through hole on the first substrate.

The method for manufacturing the display panel according to an embodiment of the present disclosure forms a first portion and a second portion which are adjacent to each other and of different thicknesses in the planarization layer, when the anode covers the lateral surface adjacent to the first portion, of the second portion, the angle between the part covering the lateral surface of the second portion, of the anode and the part covering the surface of the first portion, of the anode is greater than 0, and the part covering the lateral surface of the second portion, of the anode can be used as a reflective layer to reflect light emitted laterally by the light-emitting device, so that the lateral light leakage of subpixels can be reduced, and the display effect is improved. Moreover, the planarization layer further includes a third portion adjacent to the second portion and of a thickness different from that of the second portion. The third portion is located in the region between the light-emitting regions of the subpixels, that is, the planarization layer has a concave part in the region between the light-emitting regions of the subpixels, so that the segment difference between the light-emitting region of the subpixel and the region outside the light-emitting region of the subpixel can be increased. The concave part can accommodate the filling material in the box aligning process, and is conducive to the filling and drainage of the filling material, and can also play a pressure dividing role in the box aligning process, avoid the damage to each film layer on a side of the array substrate during the pressing process, and improve the yield of the top emission display panel. In addition, for the flexible display panel, the arrangement of the concave region can reduce the force applied to the region corresponding to the light-emitting region of the subpixel during the bending process of the display panel, which is conducive to avoiding the bending and fracture of each film layer in the region corresponding to the light-emitting region of the subpixel. In addition, the first through hole is arranged in the first portion so that the anode and the thin-film transistor are electrically connected, that is, the first through hole is formed in the region of the planarization layer with a less thickness, and the depth of the first through hole is shallower, which can reduce the difficulty of preparing the first through hole, and can also reduce the thickness of the photoresist coating in the preparation process of the first through hole, and reduce the risk of residue after the photoresist is peeled off. In addition, the orthographic projection of the pixel definition layer on the first substrate covers the orthographic projection of the first through hole on the first substrate, that is, the region corresponding to the first through hole is covered by the pixel definition layer, so that the region of the first through hole is flattened.

In some embodiments, forming the pattern of the planarization layer on the side away from the first substrate, of the driving circuit layer, includes:
depositing a planarization layer material on the side away from the first substrate, of the driving circuit layer to form the planarization layer;
forming the first portions, the second portions and the third portions by performing a halftone mask process on the planarization layer.

In some embodiments, forming the pattern of the pixel definition layer on the side away from the planarization layer, of the anode, includes:
forming the pixel definition layer on the side away from the planarization layer, of the anode;
forming a plurality of first opening regions and a plurality of second opening regions by a patterning process; an orthographic projection of the first opening region on the first substrate is within the orthographic projection of the first portion on the first substrate, an orthographic projection of the second opening region on the first substrate is within the orthographic projection of the third portion on the first substrate, and the orthographic projection of the second portion on the first substrate is within the orthographic projection of the pixel definition layer on the first substrate.

In some embodiments, after forming a pixel definition layer, the method further includes:
forming a luminescent functional layer in the first opening region;
forming a cathode on a side away from the anode, of the luminescent functional layer.

In some embodiments, after forming the cathode, the method further includes:
forming an organic encapsulation layer and an inorganic encapsulation layer sequentially on a side away from the first substrate, of the cathode.

In some embodiments, after forming the inorganic encapsulation layer, the method further includes:
forming a filling layer on a side away from the organic encapsulation layer, of the inorganic encapsulation layer, and arranging a second substrate on a side away from the first substrate, of the filling layer by a box aligning process.

In some embodiments, forming the driving circuit layer on the side of the first substrate, includes:
forming a buffer layer, an active layer, a gate insulation layer, a gate, an interlayer insulation layer, a source and a drain sequentially on the first substrate.

Some embodiments of the present disclosure further provide a display device, which includes the display panel according to embodiments of the present disclosure.

The display device according to embodiments of the present disclosure includes: a mobile phone, a tablet computer, a television, a monitor, a notebook computer, a digital photo frame, a navigation device, and any other product or part with a display function. The other indispensable components of the display device should be understood by those reasonably skilled in the art, and are not described herein and should not be used as a limitation on the present disclosure. Embodiments of the display device can refer to embodiments of the above display panel, and will not be repeated.

To sum up, in the display panel and manufacturing method therefor according to embodiments of the present disclosure, the planarization layer includes the first portion and the second portion which are adjacent to each other and of different thicknesses. The first portion corresponds to the light-emitting region of the subpixel, that is, the planarization layer has a concave part in the region corresponding to the light-emitting region of the subpixel, so that when the anode covers the lateral surface of the second portion adjacent to the first portion, the angle α between a surface at a side away from the first substrate, of the anode and a surface of the anode parallel to a plane where the first substrate is located, is greater than 0, that is, the angle between the part of the anode covering the lateral surface of the second portion and the part of the anode covering the surface of the first portion is greater than 0, and the part of the anode covering the lateral surface of the second portion can be used as a reflective layer to reflect light emitted laterally (in a direction pointing to the first portion) by the light-emitting device, so that the lateral light leakage of subpixels can be reduced, and the display effect is improved. Moreover, the planarization layer further includes the third portion adjacent to the second portion and of the thickness different from that of the second portion. The third portion is located in the region between the light-emitting regions of the subpixels, that is, the planarization layer has a concave part in the region between the light-emitting regions of the subpixels, so that the segment difference between the light-emitting region of the subpixel and the region outside the light-emitting region of the subpixel can be increased. The concave part can accommodate the filling material in the box aligning process, and is conducive to the filling and drainage of the filling material, and can also play a pressure dividing role in the box aligning process, avoid the damage to each film layer on a side of the array substrate during the pressing process, and improve the yield of the top emission display panel. In addition, for the flexible display panel, the arrangement of the concave region can reduce the force applied to the region corresponding to the light-emitting region of the subpixel during the bending process of the display panel, which is conducive to avoiding the bending and fracture of each film layer in the region corresponding to the light-emitting region of the subpixel. In addition, the first through hole is arranged in the first portion so that the anode and the thin-film transistor are electrically connected, that is, the first through hole is formed in the region of the planarization layer with a less thickness, and the depth of the first through hole is shallower, which can reduce the difficulty of preparing the first through hole, and can also reduce the thickness of the photoresist coating in the preparation process of the first through hole, and reduce the risk of residue after the photoresist is peeled off. In addition, the orthographic projection of the pixel definition layer on the first substrate covers the orthographic projection of the first through hole on the first substrate, that is, the region corresponding to the first through hole is covered by the pixel definition layer, so that the region of the first through hole is flattened.

Although embodiments of the present disclosure have been described, those embodiments may be subject to additional changes and modifications once the basic inventive concepts are known to those skilled in the art. Therefore, the attached claims are intended to be construed to include embodiments and all changes and modifications that fall within the scope of the disclosure.

Obviously, the skilled in the art may make various changes and variants to embodiments of the present disclosure without departing from the spirit and scope of embodiments of the present disclosure. Thus, if these modifications and variants of embodiments of the present disclosure fall within the scope of the claims of the present disclosure and their equivalents, the present disclosure is also intended to include such modifications and variants.

1-20. (canceled)

21. A display panel comprising a plurality of subpixels, wherein the display panel comprises:
a first substrate;
a driving circuit layer located on a side of the first substrate and comprising a plurality of thin-film transistors;
a planarization layer located on a side away from the driving circuit layer, of the first substrate, and comprising: a plurality of first portions, a plurality of second portions, and a plurality of third portions; wherein in a direction perpendicular to the first substrate, a thickness of the first portion is less than a thickness of the second portion, and a thickness of the third portion is less than the thickness of the second portion; an orthographic projection of the second portion on the first substrate encloses an orthographic projection of the first portion on the first substrate; the orthographic projection of the first portion on the first substrate covers an orthographic projection of a light-emitting region of a subpixel on the first substrate, and an orthographic projection of the third portion on the first substrate is within an orthographic projection of a region between light-emitting regions of adjacent subpixels on the first substrate; the first portion comprises a first through hole penetrating through the thickness of the first portion;
a plurality of light-emitting devices located on a side away from the first substrate, of the planarization layer; wherein the light-emitting device comprises an anode; the anode covers the first portion and a lateral surface adjacent to the first portion, of the second portion; an angle between a surface at a side away from the first substrate, of a part of the anode covering the lateral surface of the second portion and a surface parallel to a plane where the first substrate is located, of the anode, is greater than 0; the anode is electrically connected with the thin-film transistor through the first through hole; and
a pixel definition layer located on a side away from the planarization layer, of the anode;
wherein an orthographic projection of the pixel definition layer on the first substrate covers an orthographic projection of the first through hole on the first substrate.

22. The display panel of claim 21, wherein the angle between the surface at the side away from the first substrate, of the part of the anode covering the lateral surface of the second portion and the surface parallel to the plane where the first substrate is located, of the anode, is greater than or equal to 30° and less than or equal to 50°.

23. The display panel of claim 21, wherein in the direction perpendicular to the first substrate, the thickness of the first portion is equal to the thickness of the third portion.

24. The display panel of claim 23, wherein in the direction perpendicular to the first substrate, a difference between the thickness of the second portion and the thickness of the first portion is greater than or equal to 0.5 μm and less than or equal to 1 μm.

25. The display panel of claim 21, wherein the pixel definition layer comprises a plurality of first opening regions and a plurality of second opening regions; an orthographic projection of the first opening region on the first substrate is within the orthographic projection of the first portion on the first substrate, an orthographic projection of the second opening region on the first substrate is within the orthographic projection of the third portion on the first substrate; the orthographic projection of the second portion on the first substrate is within the orthographic projection of the pixel definition layer on the first substrate.

26. The display panel of claim 25, wherein a ratio of area of an overlapping region of the orthographic projection of the second portion on the first substrate and the orthographic projection of the pixel definition layer on the first substrate to area of the orthographic projection of the pixel definition layer on the first substrate is less than or equal to 76%.

27. The display panel of claim 25, wherein a maximum distance between a surface at a side away from the first substrate, of the pixel definition layer and the first portion is greater than or equal to 1.5 μm and less than or equal to 2.5 μm.

28. The display panel of claim 25, further comprising:
a plurality of auxiliary electrodes arranged in a layer same with a layer where the anode is located, and insulated from the anode; an orthographic projection of the auxiliary electrode on the first substrate is within the orthographic projection of the second portion on the first substrate.

29. The display panel of claim 28, wherein the pixel definition layer further comprises a plurality of third opening regions, and an orthographic projection of the third opening region on the first substrate is within the orthographic projection of the auxiliary electrode on the first substrate.

30. The display panel of claim 29, wherein the pixel definition layer comprises a plurality of fourth portions and a plurality of fifth portions, the fourth portion comprises the third opening region, and an orthographic projection of the fifth portion on the first substrate covers the orthographic projection of the first through hole on the first substrate;
the fourth portion and the fifth portion are connected in one piece.

31. The display panel of claim 21, wherein a transmittance of the pixel definition layer to light with a wavelength greater than or equal to 380 nm and less than or equal to 700 nm is less than 5%.

32. The display panel of claim 21, further comprising: a second substrate on a side away from the first substrate, of the pixel definition layer, and a filling layer between the second substrate and the pixel definition layer.

33. The display panel of claim 32, wherein a distance h between adjacent first opening regions satisfies:
$$h \geq a \times b / ( d - b ) ;$$
wherein a is a distance between the second substrate and the anode covering the first portion in the direction perpendicular to the first substrate, d is a distance between the second portion and the first portion in the direction perpendicular to the first substrate, and b is a maximum width of the first opening region in a direction parallel to a plane where the first substrate is located.

34. The display panel of claim 32, wherein a distance h between adjacent first opening regions satisfies:
$$h \geq a \times b / ( c - b ) ;$$
wherein a is a distance between the second substrate and the anode covering the first portion in the direction perpendicular to the first substrate, c is a maximum distance between a side away from the first substrate, of the pixel definition layer and the first portion in the direction perpendicular to the first substrate, and b is a maximum width of the first opening region in a direction parallel to a plane where the first substrate is located.

35. The display panel of claim 32, further comprising a curved-surface region;
wherein in the curved-surface region, a distance h between two adjacent first opening regions satisfies:
$$h \geq ( a - d ) \times b / ( ( \frac{1}{K} - a ) \times d \times K ) ;$$
wherein a is a distance between the second substrate and the anode covering the first portion in the direction perpendicular to the first substrate, d is a distance between the second portion and the first portion in the direction perpendicular to the first substrate, b is a maximum width of the first opening region in a direction parallel to a plane where the first substrate is located, and K is a curvature of the curved-surface region.

36. The display panel of claim 32, further comprising a curved-surface region;
in the curved-surface region, a distance h between two adjacent first opening regions satisfies:
$$h \geq ( a - c ) \times b / ( ( \frac{1}{K} - a ) \times c \times K ) ;$$
wherein a is a distance between the second substrate and the anode covering the first portion in the direction perpendicular to the first substrate, c is a maximum distance between a side away from the first substrate, of the pixel definition layer and the first portion in the direction perpendicular to the first substrate, b is a maximum width of the first opening region in a direction parallel to a plane where the first substrate is located, and K is a curvature of the curved-surface region.

37. A method for manufacturing a display panel, comprising:
forming a driving circuit layer on a side of a first substrate; wherein the driving circuit layer comprises a plurality of thin-film transistors;
forming a pattern of a planarization layer on a side away from the first substrate, of the driving circuit layer; wherein the planarization layer comprises: a plurality of first portions, a plurality of second portions, and a plurality of third portions; in a direction perpendicular to the first substrate, a thickness of the first portion is less than a thickness of the second portion, and a thickness of the third portion is less than the thickness of the second portion; an orthographic projection of the second portion on the first substrate encloses an orthographic projection of the first portion on the first substrate; the orthographic projection of the first portion on the first substrate covers an orthographic projection of a light-emitting region of a subpixel on the first substrate; an orthographic projection of the third portion on the first substrate is within an orthographic projection of a region between light-emitting regions of adjacent subpixels on the first substrate; the first portion comprises a first through hole penetrating through the first portion;
forming a plurality of anodes on a side away from the first substrate, of the planarization layer; the anode covers the first portion and a lateral surface adjacent to the first portion, of the second portion, an angle between a surface at a side away from the first substrate, of a part of the anode covering the lateral surface of the second portion and a surface parallel to a plane where the first substrate is located, of the anode, is greater than 0; the anode is electrically connected with the thin-film transistor through the first through hole; and
forming a pattern of a pixel definition layer on a side away from the planarization layer, of the anode;
wherein an orthographic projection of the pixel definition layer on the first substrate covers an orthographic projection of the first through hole on the first substrate.

38. The method of claim 37, wherein the forming the pattern of the planarization layer on the side away from the first substrate, of the driving circuit layer, comprises:
depositing a planarization layer material on the side away from the first substrate, of the driving circuit layer to form the planarization layer;
forming the first portions, the second portions and the third portions by performing a halftone masking process on the planarization layer.

39. The method of claim 37, wherein the forming the pattern of the pixel definition layer on the side away from the planarization layer, of the anode, comprises:
forming the pixel definition layer on the side away from the planarization layer, of the anode;
forming a plurality of first opening regions and a plurality of second opening regions by a patterning process; an orthographic projection of the first opening region on the first substrate is within the orthographic projection of the first portion on the first substrate, an orthographic projection of the second opening region on the first substrate is within the orthographic projection of the third portion on the first substrate, the orthographic projection of the second portion on the first substrate is within the orthographic projection of the pixel definition layer on the first substrate.

40. A display device, comprising the display panel of claim 21.
